(19) United States
(12) Patent Application Publication
(10) Pub. No.: US 2013/0095638 A1
(43) Pub. Date: Apr. 18, 2013

(54) Method of Fabricating Integrated Circuits

(71) Applicants: Andrew Leon Vella, Balmain (AU); David McLeod Johnstone, Balmain (AU); Kia Silverbrook, Balmain (AU)

(72) Inventors: Andrew Leon Vella, Balmain (AU); David McLeod Johnstone, Balmain (AU); Kia Silverbrook, Balmain (AU)

(73) Assignee: Silverbrook Research Pty Ltd

(21) Appl. No.: 13/653,285

(22) Filed: Oct. 16, 2012

Related U.S. Application Data
(60) Provisional application No. 61/548,203, filed on Oct. 17, 2011.

(51) Int. Cl. H01L 21/306

(52) U.S. Cl. CPC H01L 21/306
USPC 438/459

(57) ABSTRACT

A method of fabricating integrated circuits is provided in which sacrificial material is provided on a first surface of a substrate to define structural elements, integrated circuit material is provided on the sacrificial material to provide integrated circuit structures as defined by the structural elements, the sacrificial material is removed from the first surface of the substrate to provide partially fabricated integrated circuits defined by the integrated circuit structures, a carrier handle is attached to the partially fabricated integrated circuits, and the substrate is thinned from a second surface of the substrate opposite the first surface to provide the fabricated integrated circuits.

### FIELD OF THE INVENTION

The present invention relates to the field of integrated circuit fabrication. In particular, a method of removing sacrificial material from integrated circuit structures during fabrication is provided. More particularly, the method provides efficiency, compatibility and cost improvements over single wafer low temperature ashing processes conventionally employed to remove sacrificial materials from wafers thinned during integrated circuit fabrication by removing sacrificial material with a high temperature batch ashing process prior to wafer thinning.

### CO-PENDING APPLICATIONS

The following applications have been filed by the Applicant simultaneously with the present application:
61548204 (Docket number MEMS42PUS)

The disclosures of these co-pending applications are incorporated herein by reference.

### CROSS REFERENCES TO RELATED APPLICATIONS

Various methods, systems and apparatus relating to the present invention are disclosed in the following US patents and patent application publications filed by the Applicant or assigned to the Assignee of the present invention:

| | | | | |
|---|---|---|---|---|
| 6,405,055 | 6,628,430 | 7,136,186 | 10/920,372 | 7,145,689 |
| 7,130,075 | 7,081,974 | 7,177,055 | 7,209,257 | 7,161,715 |
| 7,154,632 | 7,158,258 | 7,148,993 | 7,075,684 | 7,158,809 |
| 11/225,172 | 11/474,280 | 11/635,482 | 11/635,526 | 11/650,545 |
| 11/653,241 | 11/653,240 | 11/758,648 | 7,241,005 | 7,108,437 |
| 6,915,140 | 6,999,206 | 7,136,198 | 7,092,130 | 7,249,108 |
| 6,566,858 | 6,331,946 | 6,246,970 | 6,442,525 | 09/517,384 |
| 09/505,951 | 6,374,354 | 7,246,098 | 6,816,968 | 6,757,832 |
| 6,334,190 | 6,745,331 | 7,249,109 | 10/203,559 | 7,197,642 |
| 7,093,139 | 10/636,263 | 10/636,283 | 10/866,608 | 7,210,038 |
| 10/902,833 | 10/940,653 | 10/942,858 | 11/706,329 | 11/757,385 |
| 11/758,642 | 7,170,652 | 6,967,750 | 6,995,876 | 7,099,051 |
| 11/107,942 | 7,193,734 | 11/209,711 | 11/599,336 | 7,095,533 |
| 6,914,686 | 7,161,709 | 7,099,033 | 11/003,786 | 7,258,417 |
| 11/003,418 | 11/003,334 | 11/003,600 | 11/003,404 | 11/003,419 |
| 11/003,700 | 7,255,419 | 11/003,618 | 7,229,148 | 7,258,416 |
| 11/003,698 | 11/003,420 | 6,984,017 | 11/003,699 | 11/071,473 |
| 11/748,482 | 11/778,563 | 11/779,851 | 11/778,574 | 11/853,816 |
| 11/853,814 | 11/853,786 | 11/856,694 | 11/003,463 | 11/003,701 |
| 11/003,683 | 11/003,614 | 11/003,702 | 11/003,684 | 7,246,875 |
| 11/003,617 | 11/764,760 | 11/853,777 | 11/293,800 | 11/293,802 |
| 11/293,801 | 11/293,808 | 11/293,809 | 11/482,975 | 11/482,970 |
| 11/482,968 | 11/482,972 | 11/482,971 | 11/482,969 | 11/097,266 |
| 11/097,267 | 11/685,084 | 11/685,086 | 11/685,090 | 11/740,925 |
| 11/763,444 | 11/763,443 | 11/518,238 | 11/518,280 | 11/518,244 |
| 11/518,243 | 11/518,242 | 11/084,237 | 11/084,240 | 11/084,238 |
| 11/357,296 | 11/357,298 | 11/357,297 | 11/246,676 | 11/246,677 |
| 11/246,678 | 11/246,679 | 11/246,680 | 11/246,681 | 11/246,714 |
| 11/246,713 | 11/246,689 | 11/246,671 | 11/246,670 | 11/246,669 |
| 11/246,704 | 11/246,710 | 11/246,688 | 11/246,716 | 11/246,715 |
| 11/246,707 | 11/246,706 | 11/246,705 | 11/246,708 | 11/246,693 |
| 11/246,692 | 11/246,696 | 11/246,695 | 11/246,694 | 11/482,958 |
| 11/482,955 | 11/482,962 | 11/482,963 | 11/482,956 | 11/482,954 |
| 11/482,974 | 11/482,957 | 11/482,987 | 11/482,959 | 11/482,960 |
| 11/482,961 | 11/482,964 | 11/482,965 | 11/482,976 | 11/482,973 |
| 11/495,815 | 11/495,816 | 11/495,817 | 6,227,652 | 6,213,588 |
| 6,213,589 | 6,231,163 | 6,247,795 | 6,394,581 | 6,244,691 |
| 6,257,704 | 6,416,168 | 6,220,694 | 6,257,705 | 6,247,794 |
| 6,234,610 | 6,247,793 | 6,264,306 | 6,241,342 | 6,247,792 |
| 6,264,307 | 6,254,220 | 6,234,611 | 6,302,528 | 6,283,582 |
| 6,239,821 | 6,338,547 | 6,247,796 | 6,557,977 | 6,390,603 |
| 6,362,843 | 6,293,653 | 6,312,107 | 6,227,653 | 6,234,609 |
| 6,238,040 | 6,188,415 | 6,227,654 | 6,209,989 | 6,247,791 |
| 6,336,710 | 6,217,153 | 6,416,167 | 6,243,113 | 6,283,581 |
| 6,247,790 | 6,260,953 | 6,267,469 | 6,588,882 | 6,742,873 |
| 6,918,655 | 6,547,371 | 6,938,989 | 6,598,964 | 6,923,526 |
| 6,273,544 | 6,309,048 | 6,420,196 | 6,443,558 | 6,439,689 |
| 6,378,989 | 6,848,181 | 6,634,735 | 6,299,289 | 6,299,290 |
| 6,425,654 | 6,902,255 | 6,623,101 | 6,406,129 | 6,505,916 |
| 6,457,809 | 6,550,895 | 6,457,812 | 7,152,962 | 6,428,133 |
| 7,216,956 | 7,080,895 | 11/144,844 | 7,182,437 | 11/599,341 |
| 11/635,533 | 11/607,976 | 11/607,975 | 11/607,999 | 11/607,980 |
| 11/607,979 | 11/607,978 | 11/735,961 | 11/685,074 | 11/696,126 |
| 11/696,144 | 11/696,650 | 11/763,446 | 10/407,212 | 7,252,366 |
| 10/683,064 | 10/683,041 | 11/766,713 | 11/841,647 | 11/482,980 |
| 11/563,684 | 11/482,967 | 11/482,966 | 11/482,988 | 11/482,989 |
| 11/293,832 | 11/293,838 | 11/293,825 | 11/293,841 | 11/293,799 |
| 11/293,796 | 11/293,797 | 11/293,798 | 11/124,158 | 11/124,196 |
| 11/124,199 | 11/124,162 | 11/124,202 | 11/124,197 | 11/124,154 |
| 11/124,198 | 11/124,153 | 11/124,151 | 11/124,160 | 11/124,192 |
| 11/124,175 | 11/124,163 | 11/124,149 | 11/124,152 | 11/124,173 |
| 11/124,155 | 7,236,271 | 11/124,174 | 11/124,194 | 11/124,164 |
| 11/124,200 | 11/124,195 | 11/124,166 | 11/124,150 | 11/124,172 |
| 11/124,165 | 11/124,186 | 11/124,185 | 11/124,184 | 11/124,182 |
| 11/124,201 | 11/124,171 | 11/124,181 | 11/124,161 | 11/124,156 |
| 11/124,191 | 11/124,159 | 11/124,176 | 11/124,188 | 11/124,170 |
| 11/124,187 | 11/124,189 | 11/124,190 | 11/124,180 | 11/124,193 |
| 11/124,183 | 11/124,178 | 11/124,177 | 11/124,148 | 11/124,168 |
| 11/124,167 | 11/124,179 | 11/124,169 | 11/187,976 | 11/188,011 |
| 11/188,014 | 11/482,979 | 11/735,490 | 11/853,018 | 11/228,540 |
| 11/228,500 | 11/228,501 | 11/228,530 | 11/228,490 | 11/228,531 |
| 11/228,504 | 11/228,533 | 11/228,502 | 11/228,507 | 11/228,482 |
| 11/228,505 | 11/228,497 | 11/228,487 | 11/228,529 | 11/228,484 |
| 11/228,489 | 11/228,518 | 11/228,536 | 11/228,496 | 11/228,488 |
| 11/228,506 | 11/228,516 | 11/228,526 | 11/228,539 | 11/228,538 |
| 11/228,524 | 11/228,523 | 11/228,519 | 11/228,528 | 11/228,527 |
| 11/228,525 | 11/228,520 | 11/228,498 | 11/228,511 | 11/228,522 |
| 11/228,515 | 11/228,537 | 11/228,534 | 11/228,491 | 11/228,499 |
| 11/228,509 | 11/228,492 | 11/228,493 | 11/228,510 | 11/228,508 |
| 11/228,512 | 11/228,514 | 11/228,494 | 11/228,495 | 11/228,486 |
| 11/228,481 | 11/228,477 | 11/228,485 | 11/228,483 | 11/228,521 |
| 11/228,517 | 11/228,532 | 11/228,513 | 11/228,503 | 11/228,480 |
| 11/228,535 | 11/228,478 | 11/228,479 | 6,087,638 | 6,340,222 |
| 6,041,600 | 6,299,300 | 6,067,797 | 6,286,935 | 6,044,646 |
| 6,382,769 | 10/868,866 | 6,787,051 | 6,938,990 | 11/242,916 |
| 11/242,917 | 11/144,799 | 11/198,235 | 11/766,052 | 7,152,972 |
| 11/592,996 | 6,746,105 | 11/763,440 | 11/763,442 | 11/246,687 |
| 11/246,718 | 11/246,685 | 11/246,686 | 11/246,703 | 11/246,691 |
| 11/246,711 | 11/246,690 | 11/246,712 | 11/246,717 | 11/246,709 |
| 11/246,700 | 11/246,701 | 11/246,702 | 11/246,668 | 11/246,697 |
| 11/246,698 | 11/246,699 | 11/246,675 | 11/246,674 | 11/246,667 |
| 11/829,957 | 11/829,960 | 11/829,961 | 11/829,962 | 11/829,963 |
| 11/829,966 | 11/829,967 | 11/829,968 | 11/829,969 | 7,156,508 |
| 7,159,972 | 7,083,271 | 7,165,834 | 7,080,894 | 7,201,469 |
| 7,090,336 | 7,156,489 | 10/760,233 | 10/760,246 | 7,083,257 |
| 7,258,422 | 7,255,423 | 7,219,980 | 10/760,253 | 10/760,255 |
| 10/760,209 | 7,118,192 | 10/760,194 | 10/760,238 | 7,077,505 |
| 7,198,354 | 7,077,504 | 10/760,189 | 7,198,355 | 10/760,232 |
| 10/760,231 | 7,152,959 | 7,213,906 | 7,178,901 | 7,222,938 |
| 7,108,353 | 7,104,629 | 11/446,227 | 11/454,904 | 11/472,345 |
| 11/474,273 | 7,261,401 | 11/474,279 | 11/482,939 | 11/482,950 |
| 11/499,709 | 11/592,984 | 11/601,668 | 11/603,824 | 11/601,756 |
| 11/601,672 | 11/650,546 | 11/653,253 | 11/706,328 | 11/706,299 |
| 11/706,965 | 11/737,080 | 11/737,041 | 11/778,062 | 11/778,566 |
| 11/782,593 | 11/246,684 | 11/246,672 | 11/246,673 | 11/246,683 |
| 11/246,682 | 7,246,886 | 7,128,400 | 7,108,355 | 6,991,322 |
| 10/728,790 | 7,118,197 | 10/728,784 | 10/728,783 | 7,077,493 |
| 6,962,402 | 10/728,803 | 7,147,308 | 10/728,779 | 7,118,198 |
| 7,168,790 | 7,172,270 | 7,229,155 | 6,830,318 | 7,195,342 |
| 7,175,261 | 10/773,183 | 7,108,356 | 7,118,202 | 10/773,186 |
| 7,134,744 | 10/773,185 | 7,134,743 | 7,182,439 | 7,210,768 |
| 10/773,187 | 7,134,745 | 7,156,484 | 7,118,201 | 7,111,926 |
| 10/773,184 | 7,018,021 | 11/060,751 | 11/060,805 | 11/188,017 |
| 7,128,402 | 11/298,774 | 11/329,157 | 11/490,041 | 11/501,767 |
| 11/499,736 | 7,246,885 | 7,229,156 | 11/505,846 | 11/505,857 |
| 11/505,856 | 11/524,908 | 11/524,938 | 7,258,427 | 11/524,912 |
| 11/592,999 | 11/592,995 | 11/603,825 | 11/649,773 | 11/650,549 |
| 11/653,237 | 11/706,378 | 11/706,962 | 11/749,118 | 11/754,937 |
| 11/749,120 | 11/744,885 | 11/779,850 | 11/765,439 | 11/842,950 |
| 11/839,539 | 11/097,308 | 11/097,309 | 7,246,876 | 11/097,299 |
| 11/097,310 | 11/097,213 | 11/210,687 | 11/097,212 | 7,147,306 |
| 7,261,394 | 11/764,806 | 11/782,595 | 11/482,953 | 11/482,977 |
| 11/544,778 | 11/544,779 | 11/764,808 | 09/575,197 | 7,079,712 |
| 6,825,945 | 09/575,165 | 6,813,039 | 6,987,506 | 7,038,797 |
| 6,980,318 | 6,816,274 | 7,102,772 | 09/575,186 | 6,681,045 |
| 6,728,000 | 7,173,722 | 7,088,459 | 09/575,181 | 7,068,382 |
| 7,062,651 | 6,789,194 | 6,789,191 | 6,644,642 | 6,502,614 |
| 6,622,999 | 6,669,385 | 6,549,935 | 6,987,573 | 6,727,996 |
| 6,591,884 | 6,439,706 | 6,760,119 | 09/575,198 | 6,290,349 |
| 6,428,155 | 6,785,016 | 6,870,966 | 6,822,639 | 6,737,591 |
| 7,055,739 | 7,233,320 | 6,830,196 | 6,832,717 | 6,957,768 |
| 09/575,172 | 7,170,499 | 7,106,888 | 7,123,239 | 11/066,161 |
| 11/066,160 | 11/066,159 | 11/066,158 | 11/066,165 | 10/727,181 |
| 10/727,162 | 10/727,163 | 10/727,245 | 7,121,639 | 7,165,824 |
| 7,152,942 | 10/727,157 | 7,181,572 | 7,096,137 | 10/727,257 |
| 7,278,034 | 7,188,282 | 10/727,159 | 10/727,180 | 10/727,179 |
| 10/727,192 | 10/727,274 | 10/727,164 | 10/727,161 | 10/727,198 |
| 10/727,158 | 10/754,536 | 10/754,938 | 10/727,227 | 10/727,160 |
| 10/934,720 | 7,171,323 | 11/272,491 | 11/474,278 | 11/488,853 |
| 11/488,841 | 11/749,750 | 11/749,749 | 10/296,522 | 6,795,215 |
| 7,070,098 | 7,154,638 | 6,805,419 | 6,859,289 | 6,977,751 |
| 6,398,332 | 6,394,573 | 6,622,923 | 6,747,760 | 6,921,144 |
| 10/884,881 | 7,092,112 | 7,192,106 | 11/039,866 | 7,173,739 |
| 6,986,560 | 7,008,033 | 11/148,237 | 7,222,780 | 11/248,426 |
| 11/478,599 | 11/499,749 | 11/738,518 | 11/482,981 | 11/743,661 |
| 11/743,659 | 11/752,900 | 7,195,328 | 7,182,422 | 11/650,537 |
| 11/712,540 | 10/854,521 | 10/854,522 | 10/854,488 | 10/854,487 |
| 10/854,503 | 10/854,504 | 10/854,509 | 7,188,928 | 7,093,989 |
| 10/854,497 | 10/854,495 | 10/854,498 | 10/854,511 | 10/854,512 |
| 10/854,525 | 10/854,526 | 10/854,516 | 10/854,508 | 7,252,353 |
| 10/854,515 | 7,267,417 | 10/854,505 | 10/854,493 | 7,275,805 |
| 10/854,489 | 10/854,490 | 10/854,492 | 10/854,491 | 10/854,528 |
| 10/854,523 | 10/854,527 | 10/854,524 | 10/854,520 | 10/854,514 |
| 10/854,519 | 10/854,513 | 10/854,499 | 10/854,501 | 7,266,661 |
| 7,243,193 | 10/854,518 | 10/854,517 | 10/934,628 | 7,163,345 |
| 11/499,803 | 11/601,757 | 11/706,295 | 11/735,881 | 11/748,483 |
| 11/749,123 | 11/766,061 | 11/775,135 | 11/772,235 | 11/778,569 |
| 11/829,942 | 11/014,731 | 11/544,764 | 11/544,765 | 11/544,772 |
| 11/544,773 | 11/544,774 | 11/544,775 | 11/544,776 | 11/544,766 |
| 11/544,767 | 11/544,771 | 11/544,770 | 11/544,769 | 11/544,777 |
| 11/544,768 | 11/544,763 | 11/293,804 | 11/293,840 | 11/293,803 |
| 11/293,833 | 11/293,834 | 11/293,835 | 11/293,836 | 11/293,837 |
| 11/293,792 | 11/293,794 | 11/293,839 | 11/293,826 | 11/293,829 |
| 11/293,830 | 11/293,827 | 11/293,828 | 11/293,795 | 11/293,823 |
| 11/293,824 | 11/293,831 | 11/293,815 | 11/293,819 | 11/293,818 |
| 11/293,817 | 11/293,816 | 11/838,875 | 11/482,978 | 11/640,356 |
| 11/640,357 | 11/640,358 | 11/640,359 | 11/640,360 | 11/640,355 |
| 11/679,786 | 10/760,254 | 10/760,210 | 10/760,202 | 7,201,468 |
| 10/760,198 | 10/760,249 | 7,234,802 | 10/760,196 | 10/760,247 |
| 7,156,511 | 10/760,264 | 7,258,432 | 7,097,291 | 10/760,222 |
| 10/760,248 | 7,083,273 | 10/760,192 | 10/760,203 | 10/760,204 |
| 10/760,205 | 10/760,206 | 10/760,267 | 10/760,270 | 7,198,352 |
| 10/760,271 | 10/760,275 | 7,201,470 | 7,121,655 | 10/760,184 |
| 7,232,208 | 10/760,186 | 10/760,261 | 7,083,272 | 11/501,771 |
| 11/583,874 | 11/650,554 | 11/706,322 | 11/706,968 | 11/749,119 |
| 11/779,848 | 11/855,152 | 11/855,151 | 11/014,764 | 11/014,763 |
| 11/014,748 | 11/014,747 | 11/014,761 | 11/014,760 | 11/014,757 |
| 11/014,714 | 7,249,822 | 11/014,762 | 11/014,724 | 11/014,723 |
| 11/014,756 | 11/014,736 | 11/014,759 | 11/014,758 | 11/014,725 |
| 11/014,739 | 11/014,738 | 11/014,737 | 11/014,726 | 11/014,745 |
| 11/014,712 | 11/014,715 | 11/014,751 | 11/014,735 | 11/014,734 |
| 11/014,719 | 11/014,750 | 11/014,749 | 7,249,833 | 11/758,640 |
| 11/775,143 | 11/838,877 | 11/014,769 | 11/014,729 | 11/014,743 |
| 11/014,733 | 11/014,754 | 11/014,755 | 11/014,765 | 11/014,766 |
| 11/014,740 | 11/014,720 | 11/014,753 | 7,255,430 | 11/014,744 |
| 11/014,741 | 11/014,768 | 11/014,767 | 11/014,718 | 11/014,717 |
| 11/014,716 | 11/014,732 | 11/014,742 | 11/097,268 | 11/097,185 |
| 11/097,184 | 11/778,567 | 11/852,958 | 11/852,907 | 11/293,820 |
| 11/293,813 | 11/293,822 | 11/293,812 | 11/293,821 | 11/293,814 |
| 11/293,793 | 11/293,842 | 11/293,811 | 11/293,807 | 11/293,806 |
| 11/293,805 | 11/293,810 | 11/688,863 | 11/688,864 | 11/688,865 |
| 11/688,866 | 11/688,867 | 11/688,868 | 11/688,869 | 11/688,871 |
| 11/688,872 | 11/688,873 | 11/741,766 | 11/482,982 | 11/482,983 |
| 11/482,984 | 11/495,818 | 11/495,819 | 11/677,049 | 11/677,050 |
| 11/677,051 | 11/014,722 | 10/760,180 | 7,111,935 | 10/760,213 |
| 10/760,219 | 10/760,237 | 7,261,482 | 10/760,220 | 7,002,664 |
| 10/760,252 | 10/760,265 | 7,088,420 | 11/446,233 | 11/503,083 |
| 11/503,081 | 11/516,487 | 11/599,312 | 11/014,728 | 11/014,727 |
| 7,237,888 | 7,168,654 | 7,201,272 | 6,991,098 | 7,217,051 |
| 6,944,970 | 10/760,215 | 7,108,434 | 10/760,257 | 7,210,407 |
| 7,186,042 | 10/760,266 | 6,920,704 | 7,217,049 | 10/760,214 |
| 10/760,260 | 7,147,102 | 10/760,269 | 7,249,838 | 10/760,241 |
| 10/962,413 | 10/962,427 | 7,261,477 | 7,225,739 | 10/962,402 |
| 10/962,425 | 10/962,428 | 7,191,978 | 10/962,426 | 10/962,409 |
| 10/962,417 | 10/962,403 | 7,163,287 | 7,258,415 | 10/962,523 |
| 7,258,424 | 10/962,410 | 7,195,412 | 7,207,670 | 11/282,768 |
| 7,220,072 | 11/474,267 | 11/544,547 | 11/585,925 | 11/593,000 |
| 11/706,298 | 11/706,296 | 11/706,327 | 11/730,760 | 11/730,407 |
| 11/730,787 | 11/735,977 | 11/736,527 | 11/753,566 | 11/754,359 |
| 11/778,061 | 11/765,398 | 11/778,556 | 11/829,937 | 11/780,470 |
| 11/223,262 | 11/223,018 | 11/223,114 | 11/223,022 | 11/223,021 |
| 11/223,020 | 11/223,019 | 11/014,730 | 7,154,626 | 7,079,292 |
| 11/604,316 | | | | |

### BACKGROUND OF THE INVENTION

Typically, integrated circuit fabrication uses sacrificial material as a temporary structural material to create cavities, suspended structures and intricate channels and as a protection material for materials used during the fabrication process. Increased complexity of the integrated circuit structures being fabricated, such as microelectronic mechanical structures of inkjet printheads, often requires many deposition and removal steps of the sacrificial material.

Removal of relatively thin layers, e.g., one micron or less, of sacrificial material, such as photoresist used as photolithographic masks, is usually simple. Accordingly, in conventional integrated circuit fabrication processes involving thin sacrificial material layers a final or late-stage removal step is used to remove the sacrificial material from the integrated circuit components. Conventional removal techniques include so-called ‘dry ashing’ which uses oxygen plasma to etch away sacrificial polymers, such as photoresist, or so-called ‘wet removal’ which uses solvent, e.g., N-Methyl-2-pyrrolidone (NMP), to remove sacrificial polymers, such as photoresist.

In conventional thin wafer processing of integrated circuit manufacture relatively large quantities of sacrificial polymer need to be removed by the end of processing. However, these relatively thick layers of sacrificial material, which have been hard baked and cured during the fabrication process, have increased resistance to removal and are removed relatively slowly by traditional oxygen plasma ashing and wet removal techniques. The removal time is also increased by the complexity of integrated circuit structures from which the sacrificial material must be removed. This is especially a problem for inkjet technologies as the fluidic pathways are quite long and often the plasma has indirect access to the sacrificial material.

Thin wafer processing also requires the wafer to be temporarily supported by glass or sapphire carrier handles during processing. The wafer is adhered to a carrier handle using a double sided adhesive wafer tape. As the wafer tape primarily consists of a polymer carrier sandwiched between layers of polymer adhesive, the ashing and wet removal processes used in final or late-stage thin wafer processing must be compatible with the polymer of the wafer tape used so that selective removal of the sacrificial material is achieved without also damaging the wafer tape.

For example, with respect to conventional oxygen plasma ashing techniques, the ashing process needs to be regulated to below 50 degree Celsius to prevent the wafer tape from overheating which would otherwise cause burning of the wafer tape and/or undesired permanent adhesion of the carrier handle to the wafer. As the sacrificial material removal rate and plasma temperature have an exponential relationship, i.e., higher temperature equals a much faster removal rate, a low temperature ashing process removes the sacrificial material at a very slow rate, e.g., a typically a total ashing time of about four hours can be expected for ashing regulated at 50 degrees Celsius.

Further, standard barrel ashing equipment allows processing of multiple wafers per cycle, so-called ‘batch’ ashing. However, barrel ashing does not provide the ability to regulate the chamber temperature. Hence, using a batch ashing approach to remove the sacrificial polymer is incompatible with thin wafer processing due to the above-described thermal constraints imposed by the wafer tape. As such, thin wafer processing relies on ‘single wafer ashing’ to remove the sacrificial polymer. This constraint further lowers the wafer throughput and significantly contributes to the overall manufacturing cost.

Further, with respect to conventional wet removal techniques, organic solvents, such as NMP, used in the wet removal process damages the wafer tape. This is particularly a problem in the manufacture of integrated circuit structures having perforated wafers which exposes the wafer tape to the organic solvent causing the wafer to separate from the carrier handle during processing.

Thus, with respect to final or late-stage ashing processes used in thin wafer processing of integrated circuits, prolonged ashing times are typically required to remove the sacrificial material due to the complex structures from which the sacrificial material has to be released and the need to protect the wafer tape and manufacturing equipment. Reduction of the ashing time can be provided, for example, by modifying the plasma used or by increasing the ashing temperature. That is, the addition of small amounts of fluorine-containing gases (e.g. CF₄, C₄F₈) is known to increase the rate of oxygen plasma ashing. However, fluorinated gas chemistries attack certain integrated circuit materials, such as silicon nitride used in inkjet technologies. Further, the use of O₂/N₂ has also been conventionally used to improve ashing rates, although the addition of N₂ shows only moderate improvement over pure O₂. Therefore, whilst there is a need to increase the efficiency of each thin wafer processing step so as to reduce the processing time and therefore the cost of each integrated circuit produced, it is clear that conventional ashing removal processes in final or late-stage thin wafer processing cannot provide such improvements.

Further, whilst wet removal processes have significantly lower cost per wafer as compared to ashing, the compatibility of the solvent with the carrier handle wafer tapes used in thin wafer processing remains an issue. A solvent that is most certainly wafer tape compatible is water. Accordingly, a water soluble material as the sacrificial material would be suitable.

US Patent Application Publication Nos. 2007/0184630 and 2010/00028812 describe water soluble polyvinyl alcohol which is compatible with thermal release wafer tapes for use as a sacrificial polymer or protective film. However, it is unknown whether water soluble polyvinyl alcohol is compatible with other wafer tapes and the Applicant has found that water soluble polyvinyl alcohol is not stable in a normal thin wafer fabrication environment since it absorbs moisture over time (about two weeks) causing swelling (about 10%), and that it has difficulty filling holes within the integrated circuit structures when used as the sacrificial material. Further, due to a number of water rinse steps used during the back-end thin water processing, conventional water soluble polyvinyl alcohol and poly(acrylic acid) may be prematurely washed away causing undesired early release of the carrier handles.

From the foregoing, it will be appreciated that there is a need to improve the efficiency of sacrificial material removal in integrated circuit fabrication techniques, particularly those manufactured using thin wafer processing, and a need to use protective materials which are compatible with the materials of the fabricated integrated circuit and the fabrication equipment.

### SUMMARY OF THE INVENTION

In one aspect, there is provided a method of fabricating integrated circuits, the method comprising:

providing sacrificial material on a first surface of a substrate to define structural elements;

providing integrated circuit material on the sacrificial material to provide integrated circuit structures as defined by the structural elements;

removing the sacrificial material from the first surface of the substrate to provide partially fabricated integrated circuits defined by the integrated circuit structures;

attaching a carrier handle to the partially fabricated integrated circuits; and

thinning the substrate from a second surface of the substrate opposite the first surface to provide the fabricated integrated circuits.

In another aspect, the removing of the photoresist is performed using oxygen plasma ashing at an elevated temperature.

In another aspect, the elevated temperature is about 200 degrees Celsius to about 350 degrees Celsius.

In another aspect, the sacrificial material is photoresist.

In another aspect, the attaching of the carrier handle is performed using temporary bond wafer tape.

In another aspect, the temporary bond wafer tape is double-sided ultraviolet release wafer tape.

In another aspect, there is provided a method of fabricating integrated circuits, the method comprising:

providing integrated circuit structures on a first surface of a substrate;

depositing a water soluble protective material on the integrated circuit structures;

attaching a first carrier handle to the protective material;

thinning the substrate from a second surface of the substrate opposite the first surface;

attaching a second carrier handle to the thinned second surface; and

removing the protective material with water to provide the fabricated integrated circuits.

In another aspect, the first surface of the substrate has openings, the protective material being deposited over the openings.

In another aspect, the protective material is selected from poly(acrylic acid), poly(acrylic acid)/poly(methyl methacrylate) copolymer, and polyvinyl alcohol.

In another aspect, the protective material has an average molecule length of at least about 5 Kilodaltons (kDa) in length so as to seal over the openings.

In another aspect, the protective material has an average molecule length of at least about 50 kDa in length.

In another aspect, the protective material has an average molecule length of at least about 200 kDa in length.

In another aspect, the attaching of the carrier handle is performed using temporary bond wafer tape.

In another aspect, the temporary bond wafer tape is double-sided ultraviolet release wafer tape.

### BRIEF DESCRIPTION OF THE DRAWINGS

Embodiments of the present invention will now be described by way of example only with reference to the accompanying drawings, in which:

FIG. 1 illustrates sacrificial material on and within a substrate for formation of integrated circuit structures;

FIG. 2 illustrates the substrate of FIG. 1 with the sacrificial material covered with integrated circuit material;

FIG. 3 illustrates the substrate of FIG. 2 after an etch process which exposes the covered sacrificial material from the integrated circuit material;

FIG. 4 illustrates the substrate of FIG. 3 after a removal process of a first embodiment which removes all of the sacrificial material;

FIG. 5 illustrates the substrate taken along line A-A of FIG. 4 after deposition of a protective layer;

FIG. 6 illustrates the substrate of FIG. 5 after an etch process of the first embodiment which connects the integrated circuit structures to an opposite surface of the substrate;

FIG. 7 illustrates the completed integrated circuit structures;

FIG. 8 illustrates the substrate of FIG. 3 after a removal process of a second embodiment which partially removes the sacrificial material;

FIG. 9 illustrates the substrate taken along line B-B of FIG. 8 after deposition of a protective layer; and

FIG. 10 illustrates the substrate of FIG. 9 after an etch process of the second embodiment for connecting the integrated circuit structures to an opposite surface of the substrate.

### DESCRIPTION OF EMBODIMENTS

As foreshadowed above, the present invention may be used in connection with any process requiring removal of sacrificial material. Therefore, the following description is made with respect to fabrication of a generic integrated circuit structure.

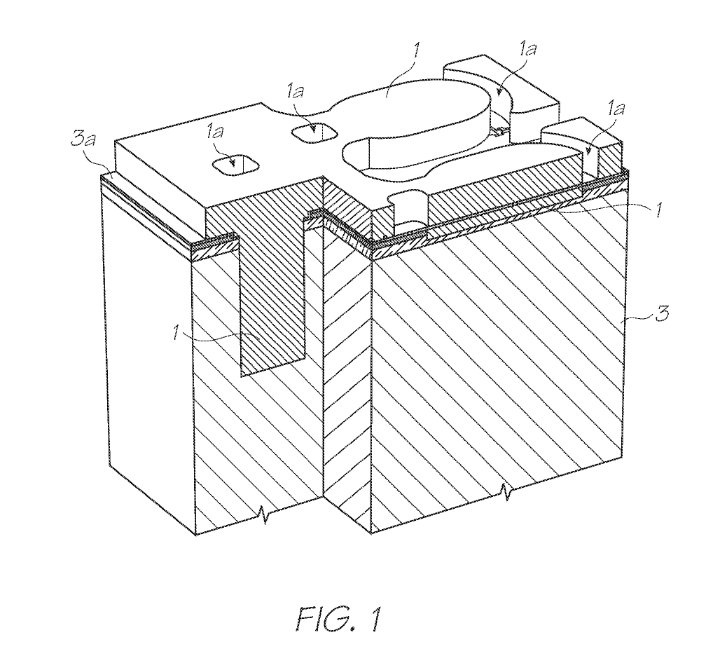

FIGS. 1-7 illustrate a first embodiment of the present invention. Referring to FIG. 1, sacrificial material 1 is provided on a first surface 3a of a substrate 3 and within the substrate 3 for later formation of integrated circuit structure(s) on and within the substrate 3. As can be seen, the sacrificial material 1 is formed with voids and recesses 1a depending on the integrated circuit being manufactured. This may be achieved, for example depending on the sacrificial material used, by etching the substrate 3 using a suitable photolithography mask to form recesses, etc., depositing the sacrificial material 1 using a suitable mask to form certain structural elements on the substrate and within the substrate recesses, and curing the sacrificial material 1 to allow it to harden. With respect to an exemplary integrated circuit being fabricated, the sacrificial material 1 may be photoresist.

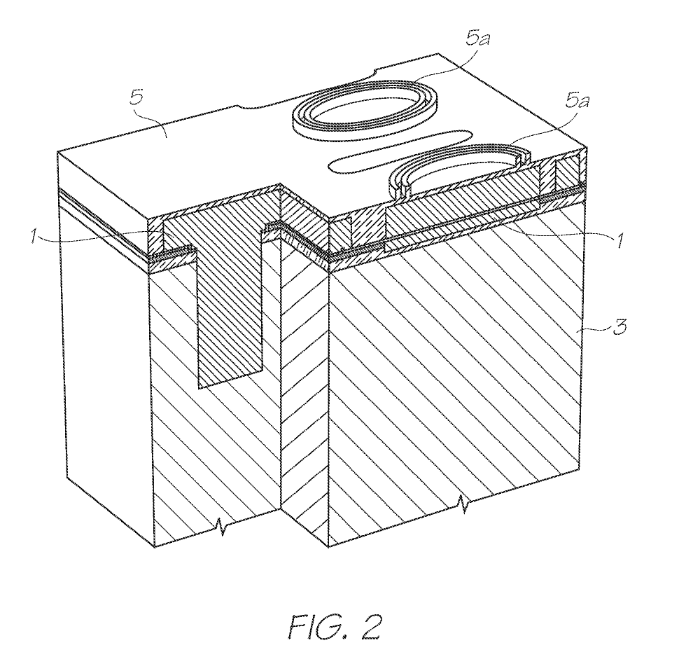

Referring to FIG. 2, integrated circuit material 5 is deposited on the sacrificial material 1 to form the basis of the integrated circuit structure. As can be seen the integrated circuit material 5 is formed with structural features 5a depending on the integrated circuit being manufactured. This may be achieved, for example, by depositing a layer of the integrated circuit material over the sacrificial material and patterning the integrated circuit material. With respect to an exemplary integrated circuit being fabricated, the integrated circuit material 5 may be silicon oxide and the structural features 5a may be inkjet nozzles and associated ink reservoirs.

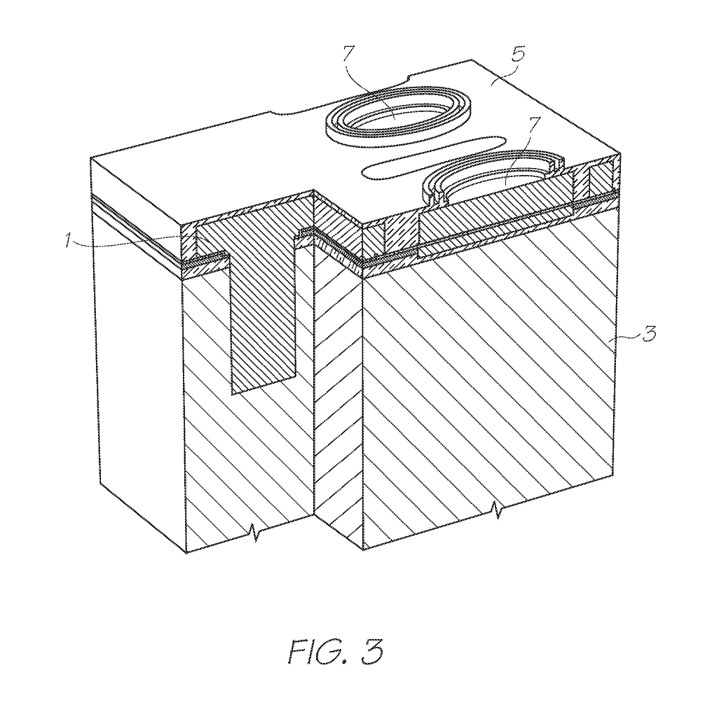

The integrated circuit material 5 is then etched at discrete locations 7, as illustrated in FIG. 3. This may be achieved, for example, by etching the integrated circuit material 5 using a suitable mask to form openings 7 in the integrated circuit material 5 in associated with some of the structural features 5a. This etching exposes the sacrificial material 1 to the external environment which allows subsequent removal of the sacrificial material 1 through the openings 7. With respect to the exemplary integrated circuit being fabricated, the openings 7 may be ejection ports of the inkjet nozzles which are connected to the ink reservoirs and other parts of the integrated circuit.

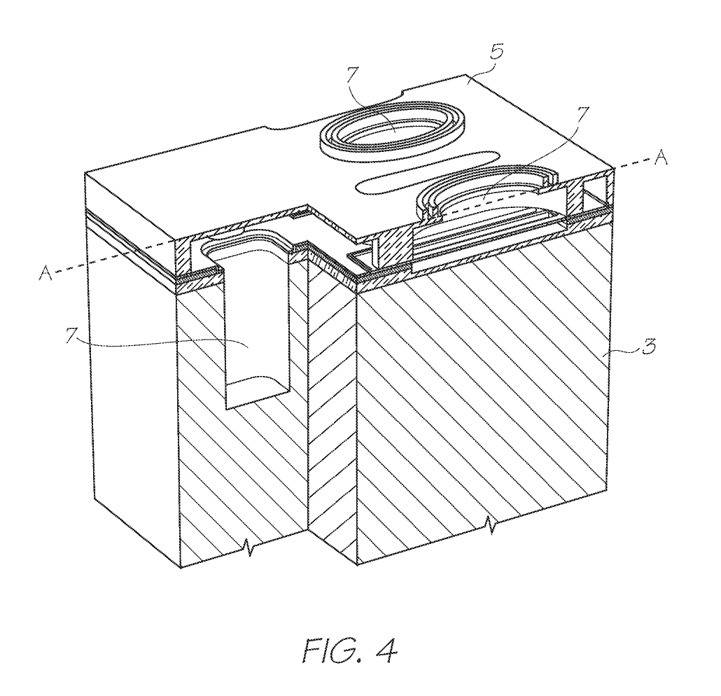

All of the sacrificial material 1 is then removed as illustrated in FIG. 4. This may be achieved, for example depending on the sacrificial material used, by using oxygen plasma ashing at elevated temperature to completely remove the sacrificial material 1 thereby leaving the integrated circuit structure. A particular example of the elevated temperature ashing process is described later.

A layer of protective material 9 is then deposited on a surface 5b of the integrated circuit material 5 to cover the openings 7, as illustrated in FIG. 5. In particular, the illustrated layer of the protective material 9 seals over the exposed openings 7 of the structural features 5a without being deposited within the openings 7. This may be achieved, for example depending on the protective material used, by spin coating the structural features 5a and surface 5b of the integrated circuit material 5 with the protective material 9 and curing the protective material 9 to allow it to harden.

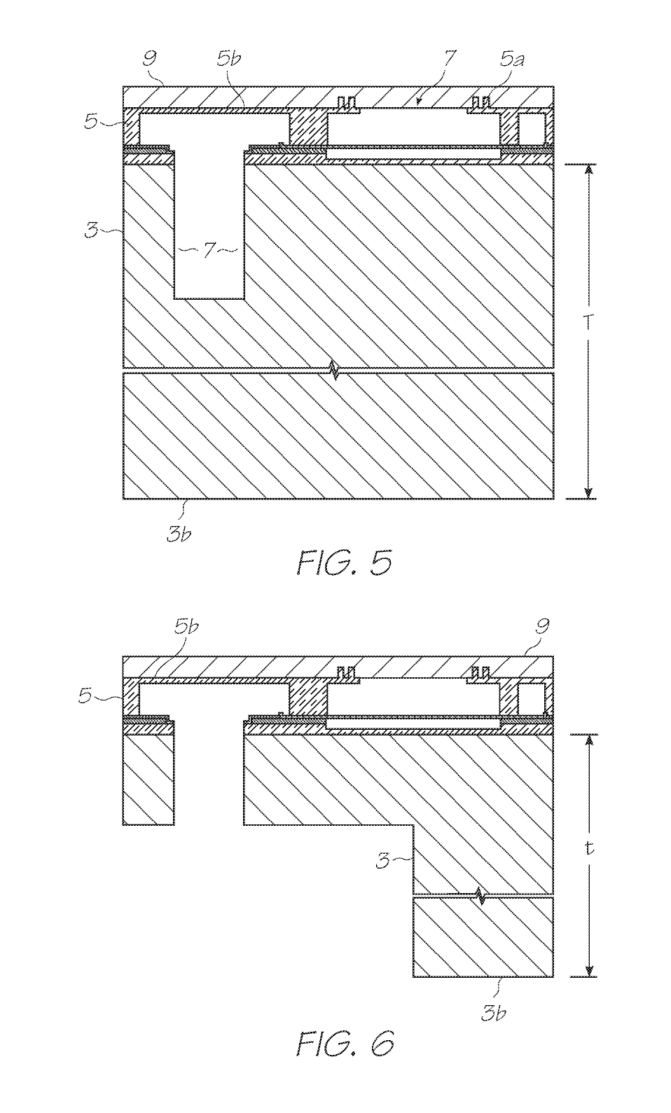

Once the protective material 9 is in place, further integrated circuit processing can be carried out on the substrate 3, so-called ‘back-end’ thin wafer processing. This back-end processing may include attachment of a first carrier handle to the surface 5a of the integrated circuit material 5 using a temporary bond wafer tape via the protective layer 9, processing the substrate 3 from a second surface 3b, which is opposite the first surface 3a, including thinning the substrate 3 (i.e., from thickness T illustrated in FIG. 5 to thickness t illustrated in FIG. 6, where t is less than T, e.g., T=725 micrometers, t=170 micrometers) and etching the substrate 3 at discrete locations 7 to connect at least some of the integrated circuit structure from the first surface 3a with the second surface 3b via channels 7, as illustrated in FIG. 6, attaching a second carrier handle to the second surface 3b using a temporary bond wafer tape, and removing the first handle from the surface 5a of the integrated circuit material 5. With respect to the exemplary integrated circuit being fabricated, the channels 7 may be fluidic pathways connected to the ink reservoir and other parts of the integrated circuit structure.

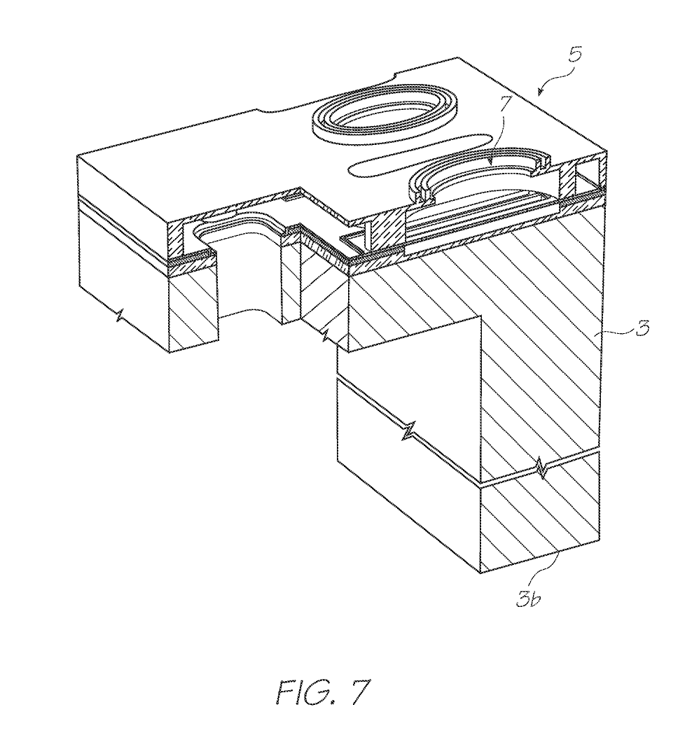

Referring to FIG. 7, the protective material 9 is then removed from the surface 5a of the integrated circuit material 5. This may be achieved, for example depending on the protective material used, by using a wet removal process to remove the protective material 9. With respect to the exemplary integrated circuit being fabricated, the removal of the protective material 9 may complete the fabrication process of the integrated circuit.

It is to be understood that the integrated circuit structure illustrated in the drawings in connection with the method of the first embodiment is merely exemplary. In the method of the first embodiment it can be seen that the removal of the sacrificial material used to define integrated circuit structures is performed prior to the back-end fabrication processes including the attachment of the carrier handles, photolithography, baking, curing, etching etc. In this way, the sacrificial material removal process can be performed at an elevated temperature (at about 200 degrees Celsius to about 350 degrees Celsius) since the temperature constraint imposed by the wafer tape used to bond the wafer to the carrier handle is not a factor. Thus, the amount of time needed to remove the sacrificial material is shortened whilst avoiding the possibility of damaging the temporary wafer tape used to attach the support handle. As will be seen from the below example of the method of the present invention, the ashing time can be significantly reduced from 130 minutes per wafer for low temperature ashing imposed by the wafer tape constraint to four minutes per wafer for the front-end ashing of the present invention.

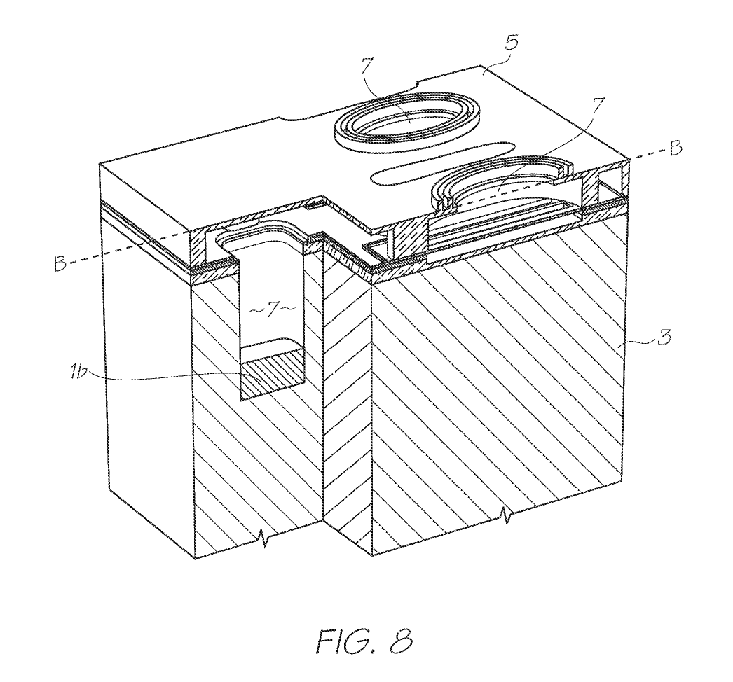

FIGS. 8-10 illustrate a part of a second embodiment of the present invention. In the second embodiment, sacrificial material 1 and integrated circuit material 5 are deposited and patterned and openings 7 are formed, as illustrated in FIGS. 1-3 of the first embodiment. Then, instead of removing all of the sacrificial material 1 as illustrated in FIG. 4 of the first embodiment, oxygen plasma ashing at the above-described elevated temperature of the first embodiment is used to partially remove the sacrificial material 1. In particular, as illustrated in FIG. 8, the ashing is performed for a length of time which removes the sacrificial material 1 from substantially all of the integrated circuit structure leaving a portion 1b of the sacrificial material 1 within one of the openings 7 which later becomes the channel 7 to the second surface 3b of the substrate 3.

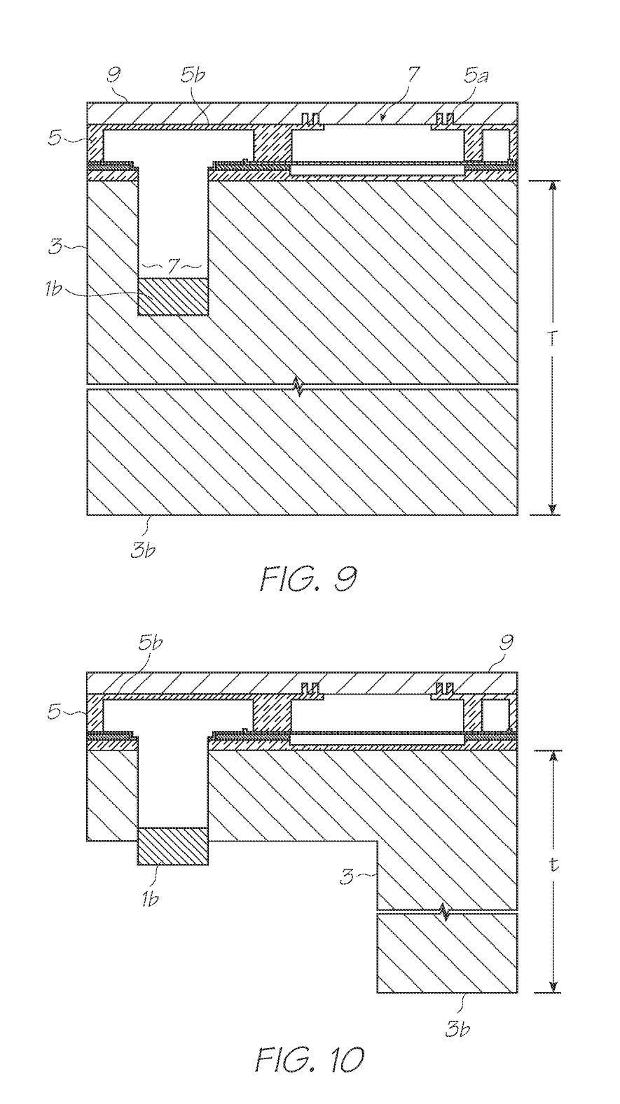

Then, as illustrated in FIG. 9, a layer of the protective material 9 is deposited in the same manner as illustrated in FIG. 5 of the first embodiment. Then, as illustrated in FIG. 10, back-end thin wafer processing is performed with some modifications from the first embodiment. These modifications include over-etching the substrate material with respect to the portion 1b of the sacrificial material 1 when etching the substrate 3 at the discrete locations 7 so that some of the sacrificial material portion 1b projects from the etched second surface 3b of the substrate 3 (see FIG. 10). Then, the sacrificial material portion 1b is removed by oxygen plasma ashing at a non-elevated temperature thereby connecting the integrated circuit structure with the second surface 3b via the channels 7 and the protective material 9 is removed to complete the integrated circuit structure as illustrated in FIG. 7 of the first embodiment.

It is to be understood that the integrated circuit structure illustrated in the drawings in connection with the method of the second embodiment is merely exemplary. In the method of the second embodiment it can be seen that most of the sacrificial material used to define integrated circuit structures is removed prior to the back-end fabrication processes and the remainder of the sacrificial material is removed during/after the back-end fabrication processes.

In particular, the sacrificial material is quickly removed from the complex areas of the integrated circuit structure, e.g., ink chambers and channels within an inkjet structure, by ashing at an elevated temperature (at about 200 degrees Celsius to about 350 degrees Celsius like the first embodiment) whilst leaving a portion of the sacrificial material to protect the integrated circuit structure from the various back-end processes performed from the second surface 3b, so-called ‘backside’, of the wafer 3. These backside processes include various chemical etching and solvent rinse steps which could otherwise cause damage to the integrated circuit structure.

Leaving only a relatively small portion of the sacrificial material to be removed from an area of the wafer which is easily accessible to the oxygen plasma means that the amount of time for the ashing process is reduced. This is the case, even when a temperature which is compatible with the wafer bond tape is used to adhere the second carrier handle to the wafer, e.g., the back-end partial ashing of the second embodiment can be performed at below about 50 degrees Celsius without adversely effecting the manufacturing time.

The early-stage removal of most or all of the sacrificial material used to define integrated circuit structures prior to the back-end thin wafer processing means that some other protective material is needed to protect the various materials and structures of the integrated circuit during further fabrication. As described above, the protective layer 9 is employed in the present invention to provide this protective function after the removal of the sacrificial material 1, and is removed by a wet removal process rather than dry ashing in the final or late-stage thin wafer processing.

As discussed earlier, using water as the solvent in the wet removal process ensures compatibility with the wafer tapes used to bond the carrier handles during the thin wafer processing. However, as also discussed earlier the use of conventional water soluble polymer as the material of the protective layer 9 has other significant problems.

The Applicant has investigated and developed certain water soluble polymers for their suitability as the material of the protective layer 9 where the wafer tape used to bond the carrier handles during the back-end thin wafer processing is UV release tape and many back-end processing steps are performed, such as grinding, photolithography, distilled water rinses, silicon etch, plasma ashing, carrier handle transfer, etc.

One of the areas investigated by the Applicant is the use of water soluble polymers to seal over the exposed openings 7, e.g., open ejection ports or fluidic pathways of inkjet nozzles, without being deposited within the openings 7 as in the above-described example. This provides the benefit of protecting the integrated circuit structures within the openings during back-end thin wafer processing without later requiring deep washing of the water soluble polymers 9 from the integrated circuit structures which undesirably exposes the integrated circuit structures to the solvent used, i.e., water.

This sealing over the openings 7 is provided by tuning of the solution viscosity and application process of the water soluble polymer 9. Selecting an appropriate molecular weight water soluble polymer provides a means of controlling the solution viscosity and penetration of water into the water soluble polymer coating. This is desirable because the back-end process involves water rinse steps, e.g., with distilled water at 25 degrees Celsius or room temperature, and therefore premature removal of the water soluble polymer is otherwise possible. The Applicant tuned the molecular weight, polymer loading, viscosity and application process through the following experimentation:

### Average Molecular Weight (Polymer Chain Length)

The viscosity of the water soluble polymer solution influences the polymer application and removal processes including the bake temperature, film thickness and dissolution rate. The solution viscosity is directly dependent on the average molecular weight of the polymer, i.e., the length of each polymer chain within the polymer solution. Accordingly, the viscosity is tuned by selecting a water soluble polymer with a suitable molecular weight. For example, the Applicant found that a water soluble polymer, such as poly(acrylic acid), with an average molecule length of at least about 5 Kilodaltons (kDa) in length is suitable for sealing over the openings 7. Preferably the average molecule length is at least about 50 kDa in length. More preferably, the average molecule length is at least about 200 kDa in length. These poly(acrylic acid) molecular weights of 5 kDa 50% aq., 50 kDa 25% aq. and 200 kDa 25% aq. provide solutions with viscosities of about 492 centipoise (cP), 198 cP and 1,075 cP, respectively.

### Polymer Loading

Adjusting the polymer loading is another means of controlling the solution viscosity, i.e., more polymer per unit of solution means higher viscosity. Water soluble polymer having an average molecule length of at least about four million kDa and 450 kDa in length in free powder form was used to make up a series of solutions of varying concentration. The Applicant found that higher molecular weight and higher polymer loading increased the solution viscosity, allowing the creation of a thicker protective layer 9 on the wafer of about six micrometers. Such a thick protective layer 9 effectively blankets the integrated circuit structures thereby protecting the surface during wafer thinning and subsequent processing.

In particular, polyvinyl chloride, such as Elvanol PVOH® or Emulsitone Solution 1146 (‘EMS1146’), which is used as a protective coating for laser scribing (therefore fabrication clean room compatible and integrated circuit friendly), was tested with various polymer loadings, providing solutions with viscosities of 7 cP, 100 cP and 400 cP. The Applicant found best results using the 400 cP solution.

### Modifying the Film Solubility by Adjusting the Spin Speed and Bake Temperature/Duration

The spin speed, ramp speed and bake conditions of spin coating the wafer with the water soluble polymer on 4-6 inch and 8 inch spin coaters were varied. The spin coated water soluble polymer is heat treated to evaporate all moisture making the polymer more resilient to moisture uptake during thin wafer processing. In particular, the water soluble polymer is spin coated onto a sample wafer and baked for five minutes at various temperatures, e.g., 100 degrees Celsius, 200 degrees Celsius and 300 degrees Celsius. The Applicant found that the bake temperature (and time) influenced the polymer removal rate (and moisture uptake), as too high a temperature caused blistering of the spin coated water soluble polymer films and too low a temperature failed to dehydrate the spin coated water soluble polymer films. The Applicant therefore found that the bake temperature needs to be below the solution boiling point to prevent film blistering.

In particular, the Applicant found the post application baking needed to occur in two stages to avoid blistering of the water soluble protective coating. The optimum first stage bake was found to be about 85 degrees Celsius for five minutes, which is approximately 25 degrees Celsius below the solution boiling point. This allowed the water to slowly evaporate from the coatings without bubbling or blistering. The second stage bake at about 200 degrees Celsius for five minutes was then used to provide further density to the coating. The use of a two stage baking process was found to be especially important for thicker coatings.

### Removal Process

The spin coated wafers were placed in a heated water bath to remove the water soluble polymers described above. The Applicant found that temperatures of between about 65 degrees Celsius and 85 degrees Celsius suitably removed the water soluble polymers. A temperature of about 65 degrees Celsius is preferable as higher temperatures pose a scolding risk to the equipment operator.

Through the above-described experimentation, the Applicant has found that the determined range of average molecule lengths provide a sufficiently high viscosity of the water soluble polymer 9 that allows clean removal of the water soluble polymer 9 from the substrate 3 and integrated circuit material 5 in a water bath at about 65 degrees Celsius whilst surviving removal by the water rinse steps at room temperature used in the back-end processing of the integrated circuit. In particular, poly(acrylic acid), poly(acrylic acid)/poly(methyl methacrylate) copolymer, and polyvinyl alcohol, having the described characteristics are compatible.

Further to the above-described advantages of ashing the sacrificial material 1 before back-end wafer thinning processing and wet removal of high viscosity water soluble polymer after back-end wafer thinning processing, this timed combination of ashing and wet removal of the method of the present invention also provides a means of processing the integrated circuit wafer on thermoplastic film frame, i.e., the standard second carrier handle used for dicing type applications followed by die picking applications, including removal of the sacrificial/protective polymer material while the wafer is mounted on the film frame. This is because, the thermoplastic film frame polymer, e.g., V8-L from Nitto Denko, is designed to soften and stretch upon heating so as to allow a die picking tool to remove the diced wafer from the film frame. Accordingly, the nature of this film frame polymer is completely incompatible with an ashing type process (even low temperature ashing). Thus, the omission of ashing during back-end processing in the method of the present embodiment enables processing on film frame which is preferred as it is a lower cost, lower contamination solution as compared to glass carrier handles and thermal release wafer tape.

### Fabrication Example

The following is a specific example of the above-described general method described in relation to FIGS. 1-7 with respect to a single integrated circuit unit.

The substrate 3 is provided as a bulk silicon wafer, e.g., a 200 mm silicon wafer of about 725 micrometer thickness or a wafer following CMOS processing.

A recess which later becomes one of the openings 7 in the substrate 3 is formed by applying a photoresist using a spin coater track system equipment, to the wafer surface, performing lithography by exposing the wafer using lithography system, e.g., Nikon Scanner equipment, developing the photoresist, performing a deionized water rinse, performing an SF₆ etch process to remove the exposed silicon, e.g., using LAM etcher equipment, performing another deionized water rinse, and performing an oxygen plasma ashing process to substantially completely remove the photoresist.

The recess and surface 3a of the substrate 3 is coated with the sacrificial material 1 as photoresist using a spin coater track system and the photoresist 1 is exposed using a lithography system, e.g., an i-line lithography system to pattern the photoresist 1 as illustrated in FIG. 1.

The photoresist 1 is covered with the integrated circuit material 5, e.g., using plasma enhanced chemical vapor deposition (PECVD) of silicon dioxide using STS PECVD deposition equipment.

The openings 7 are etched in the substrate 3 from the surface 5a of the silicon nitride 5 by applying photoresist to the surface 5a using a spin coater track system, e.g., TEL Coater Track equipment, exposing the photoresist using a lithography system, e.g., Nikon Scanner equipment, and etching through the silicon dioxide and silicon nitride layers using an oxide etcher, e.g., LAM Etcher equipment.

The photoresist of the sacrificial material 1 and the photoresist used to form the openings 7 are substantially completely removed by ashing by exposing the substrate 3 to an oxygen plasma environment at an elevated temperature for four minutes, e.g., using oxygen gas in Mattson Asher equipment heated to about 350 degrees Celsius.

The protective material 9 as poly(acrylic acid) or polyvinyl alcohol (supplied by Polysciences, Inc.) water soluble polymers is then applied to the surface 5a of the silicon nitride 5 using a photolithography track system, e.g., SVG Track equipment.

The first carrier handle as an eight inch glass wafer (supplied by Schott) bonded to a double-sided ultraviolet (UV) release wafer tape (supplied by Furukawa), is bonded to the protective material 9, e.g., using tape applicator equipment.

After processing of the substrate 3 from the second surface 3b, the second carrier handle as an eight inch glass wafer (supplied by Schott) bonded to a double sided thermal release wafer tape (supplied by Nitto Denko), is bonded to the second surface 3b, e.g., using tape applicator equipment.

The substrate 3 is released from the first carrier handle by irradiating the tape with UV light to reduce the adhesive strength.

After any further processing of the substrate from the first surface 3a, the water soluble polymer of the protective material 9 is removed though exposure to heated water, e.g., using a re-circulated water bath heated to about 65 degrees Celsius.

It will be appreciated by one of ordinary skill in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A method of fabricating integrated circuits, the method comprising:
providing sacrificial material on a first surface of a substrate to define structural elements;
providing integrated circuit material on the sacrificial material to provide integrated circuit structures as defined by the structural elements;
removing the sacrificial material from the first surface of the substrate to provide partially fabricated integrated circuits defined by the integrated circuit structures;
attaching a carrier handle to the partially fabricated integrated circuits; and
thinning the substrate from a second surface of the substrate opposite the first surface to provide the fabricated integrated circuits.

2. A method according to claim 1, wherein the removing of the photoresist is performed using oxygen plasma ashing at an elevated temperature.

3. A method according to claim 2, wherein the elevated temperature is about 200 degrees Celsius to about 350 degrees Celsius.

4. A method according to claim 2, wherein the sacrificial material is photoresist.

5. A method according to claim 1, wherein the attaching of the carrier handle is performed using temporary bond wafer tape.

6. A method according to claim 5, wherein the temporary bond wafer tape is double-sided ultraviolet release wafer tape.
